(19) United States
(12) Patent Application Publication
(10) Pub. No.: US 2020/0220544 A1
(43) Pub. Date: Jul. 9, 2020

(54) NOISE CANCELLATION CIRCUIT AND OPERATING METHOD THEREOF

(71) Applicant: Raydium Semiconductor Corporation, Hsinchu (TW)

(72) Inventor: Chih-Hsiung CHEN, Zhubei City (TW)

(21) Appl. No.: 16/734,489

(22) Filed: Jan. 6, 2020

(30) Foreign Application Priority Data
Jan. 8, 2019 (TW) 108100754

(51) Int. Cl. H03K 17/96

(52) U.S. Cl. CPC H03K 17/962; G01R 27/2605; H03K 2217/960735; H03K 2217/96015

(57) ABSTRACT

A noise cancellation circuit includes a first switch to a fourteenth switch, a first/second analog buffer, a first/second feedback capacitor, a first/second parallel capacitor, a first/second current conveyor, a first/second operation amplifier and a first/second series capacitor. In a first phase, the first switch and second switch are turned on and the remaining switches are not turned on. In a second phase, the third to fifth switches, the eighth to ninth switches and the twelfth to fourteenth switches are turned on and the remaining switches are not turned on. In a third phase, the first switch and the second switch are turned on and the remaining switches are not turned on. In a fourth phase, the third to fifth switches, the seventh switch, the tenth switch and the twelfth to fourteenth switches are turned on and the remaining switches are not turned on.

### BACKGROUND OF THE INVENTION

### 1. Field of the Invention

The invention relates to noise cancellation; in particular, to a noise cancellation circuit and an operating method thereof.

### 2. Description of the Prior Art

In a capacitor detection environment with large external noise, in order to avoid the situation that the external noise and signal changes cannot be fully reflected due to the oversaturation of the output terminal of the analog front end (AFE), the conventional solutions can be divided into the following three types:

(1) Amplified feedback capacitor mechanism: As shown in FIG. 1, since the output voltage Vout is inversely proportional to the feedback capacitor Cf, when the feedback capacitor Cf increases, the output voltage Vout will become smaller.

(2) Current mirror mechanism: As shown in FIG. 2, the original input current IN is reduced to IN/α through the current conveyor 22. Since the output voltage Vout is inversely proportional to the ratio α, when the ratio α increases, the output voltage Vout will become smaller.

(3) Differential mechanism: As shown in FIG. 3, since the obtained output voltage change is the difference between the two differential output voltages Voutp and Voutn, it will be proportional to the difference between two noise voltages Vn1 and Vn2 of two channels. Therefore, the common-mode noise can be reduced.

However, there are many disadvantages to the above-mentioned three conventional solutions, in which the disadvantages of the amplified feedback capacitor mechanism include increasing the power consumption of the analog front-end, increasing the required circuit area, decreasing the input signal-to-noise ratio and increasing detection difficulty, etc.; the disadvantages of the current mirror mechanism include decreasing the input signal-to-noise ratio and increasing detection difficulty; the disadvantages of the differential mechanism include the obtained output voltage change is the difference between channels which will cause the complexity of the back-end digital signal processing and require additional processing of boundary conditions. Therefore, it still needs to be further improved.

### SUMMARY OF THE INVENTION

Therefore, the invention provides a noise cancellation circuit and an operating method thereof to solve the above-mentioned problems occurred in the prior arts.

An embodiment of the invention is a noise cancellation circuit. In this embodiment, the noise cancellation circuit includes a first switch to a fourteen switch, a first analog buffer, a first feedback capacitor, a first parallel capacitor, a second analog buffer, a second switch, a second feedback capacitor, a second parallel capacitor, a first current conveyor, a second current conveyor, a first operation amplifier, a first series capacitor, a second operation amplifier and a second series capacitor. The first analog buffer is configured to receive a first input signal. The first switch is coupled to the first analog buffer. The first feedback capacitor is coupled between the first switch and a ground terminal. The first parallel capacitor is coupled between the first switch and a first noise voltage. The second analog buffer is configured to receive a second input signal. The second switch is coupled to the second analog buffer. The second feedback capacitor is coupled between the second switch and the ground terminal. The second parallel capacitor is coupled between the second switch and a second noise voltage. The third switch is coupled to the first switch, the first feedback capacitor and the first parallel capacitor respectively. The first current conveyor has a first input terminal, a second input terminal, a first pair of output terminals and a second pair of output terminals, wherein the first input terminal is coupled to the third switch and the second input terminal is coupled to a reference voltage. The fourth switch is coupled to the second switch, the second feedback capacitor and the second parallel capacitor respectively. The second current conveyor has a third input terminal, a fourth input terminal, a third pair of output terminals and a fourth pair of output terminals, wherein the third input terminal is coupled to the fourth switch and the fourth input terminal is coupled to the reference voltage. The fifth switch and the sixth switch are coupled to the first pair of output terminals. The seventh switch and the eighth switch are coupled to the second pair of output terminals. The ninth switch and the tenth switch are coupled to the third pair of output terminals. The eleventh switch and the twelfth switch are coupled to the fourth pair of output terminals. An input terminal of the first operation amplifier is coupled to the fifth switch, the sixth switch, the eleventh switch and the twelfth switch respectively, another input terminal of the first operation amplifier is coupled to the reference voltage, and an output terminal of the first operation amplifier outputs a first output signal. The first series capacitor is coupled between the output terminal and the input terminal of the first operation amplifier. The thirteen switch is coupled among the input terminal of the first operation amplifier, the eleventh switch and the twelfth switch. An input terminal of the second operation amplifier is coupled to the seventh switch, the eighth switch, the ninth switch and the tenth switch respectively, another input terminal of the second operation amplifier is coupled to the reference voltage, and an output terminal of the second operation amplifier outputs a second output signal. The second series capacitor is coupled between the output terminal and the input terminal of the second operation amplifier. The fourteen switch is coupled among the input terminal of the second operation amplifier, the seventh switch and the eighth switch.

In an embodiment, when the noise cancellation circuit is operated in a first phase, the first switch and the second switch are turned on and the third switch to the fourteen switch are turned off; the first input signal and the second input signal both have a first voltage; the first feedback capacitor, the first parallel capacitor, the second feedback capacitor and the second parallel capacitor are all charged to the first voltage, and the first voltage is higher than the reference voltage.

In an embodiment, when the noise cancellation circuit is operated in a second phase, the third switch to the fifth switch, the eighth switch to the ninth switch and the twelfth switch to the fourteenth switch are turned on and the first switch to the second switch, the sixth switch to the seventh switch and the tenth switch to the eleventh switch are turned off; the first output signal and the second output signal are both differential signals.

In an embodiment, when the noise cancellation circuit is operated in a third phase, the first switch and the second switch are turned on and the third switch to the fourteen switch are turned off; the first input signal has the first voltage and the second input signal has a second voltage; the first feedback capacitor and the first parallel capacitor are charged to the first voltage and the second feedback capacitor and the second parallel capacitor are charged to the second voltage; the second voltage is lower than the reference voltage and the reference voltage is an average value of the first voltage and the second voltage.

In an embodiment, when the noise cancellation circuit is operated in a fourth phase, the third switch to the fifth switch, the seventh switch, the tenth switch and the twelfth switch to the fourteenth switch are turned on and the first switch to the second switch, the sixth switch, the eighth switch to the ninth switch and the eleventh switch are turned off; the first output signal and the second output signal are both single-ended signals.

In an embodiment, the noise cancellation circuit is applied to cancel noise of capacitive touch sensing to increase accuracy of capacitive touch sensing.

Another embodiment of the invention is a noise cancellation circuit operating method. In this embodiment, the noise cancellation circuit operating method is used to operate a noise cancellation circuit. The noise cancellation circuit includes a first switch to a fourteen switch, a first analog buffer, a first feedback capacitor, a first parallel capacitor, a second analog buffer, a second switch, a second feedback capacitor, a second parallel capacitor, a first current conveyor, a second current conveyor, a first operation amplifier, a first series capacitor, a second operation amplifier and a second series capacitor. The first analog buffer receives a first input signal and the second analog buffer receives a second input signal. The first switch is coupled to the first analog buffer and the second switch is coupled to the second analog buffer. The first feedback capacitor is coupled between the first switch and a ground terminal and the second feedback capacitor is coupled between the second switch and the ground terminal. The first parallel capacitor is coupled between the first switch and a first noise voltage and the second parallel capacitor is coupled between the second switch and a second noise voltage; the third switch is coupled to the first switch, the first feedback capacitor and the first parallel capacitor respectively and the fourth switch is coupled to the second switch, the second feedback capacitor and the second parallel capacitor respectively; the first current conveyor has a first input terminal, a second input terminal, a first pair of output terminals and a second pair of output terminals; the first input terminal is coupled to the third switch and the second input terminal is coupled to a reference voltage; the second current conveyor has a third input terminal, a fourth input terminal, a third pair of output terminals and a fourth pair of output terminals; the third input terminal is coupled to the fourth switch and the fourth input terminal is coupled to the reference voltage; the fifth switch and the sixth switch are coupled to the first pair of output terminals; the seventh switch and the eighth switch are coupled to the second pair of output terminals; the ninth switch and the tenth switch are coupled to the third pair of output terminals; the eleventh switch and the twelfth switch are coupled to the fourth pair of output terminals; an input terminal of the first operation amplifier is coupled to the fifth switch, the sixth switch, the eleventh switch and the twelfth switch respectively, another input terminal of the first operation amplifier is coupled to the reference voltage, and an output terminal of the first operation amplifier outputs a first output signal; the thirteen switch is coupled among the input terminal of the first operation amplifier, the eleventh switch and the twelfth switch; an input terminal of the second operation amplifier is coupled to the seventh switch, the eighth switch, the ninth switch and the tenth switch respectively, another input terminal of the second operation amplifier is coupled to the reference voltage, and an output terminal of the second operation amplifier outputs a second output signal; the fourteen switch is coupled among the input terminal of the second operation amplifier, the seventh switch and the eighth switch; the first series capacitor is coupled between the output terminal and the input terminal of the first operation amplifier; the second series capacitor is coupled between the output terminal and the input terminal of the second operation amplifier.

The noise cancellation circuit operating method includes steps of: (a) when the noise cancellation circuit is operated in a first phase, turning on the first switch and the second switch and turning off the third switch to the fourteen switch; (b) when the noise cancellation circuit is operated in a second phase, turning on the third switch to the fifth switch, the eighth switch to the ninth switch and the twelfth switch to the fourteenth switch and turning off the first switch to the second switch, the sixth switch to the seventh switch and the tenth switch to the eleventh switch; (c) when the noise cancellation circuit is operated in a third phase, turning on the first switch and the second switch and turning off the third switch to the fourteen switch; and (d) when the noise cancellation circuit is operated in a fourth phase, turning on the third switch to the fifth switch, the seventh switch, the tenth switch, the twelfth switch to the fourteenth switch and turning off the first switch to the second switch, the sixth switch, the eighth switch to the ninth switch and the eleventh switch.

Compared to the prior art, the noise cancellation circuit of the invention uses a differential structure to eliminate noise and uses a signal modulation mechanism to modulate back to a single-ended channel change, which can not only effectively reduce external environmental noise, but also prevent the system processing complexity from increasing. Therefore, the disadvantages of the prior art can be greatly improved, and the noise cancellation circuit of the invention can be applied to noise cancellation of capacitive touch sensing to effectively improve the accuracy of capacitive touch sensing.

The advantage and spirit of the invention may be understood by the following detailed descriptions together with the appended drawings.

### BRIEF DESCRIPTION OF THE APPENDED DRAWINGS

FIG. 1 is a schematic diagram showing a conventional amplifying feedback capacitor mechanism.

FIG. 2 is a schematic diagram showing a conventional current mirror mechanism.

FIG. 3 is a schematic diagram showing a conventional differential mechanism.

FIG. 4 is a schematic diagram showing a noise cancellation circuit in a preferred embodiment of the invention.

FIG. 5 shows the simulation results when the first parallel capacitor Cp1 and the second parallel capacitor Cp2 are both equal to 10 P without external noise.

FIG. 6 shows the simulation results when the first parallel capacitor Cp1 is equal to 8 p and the second parallel capacitor Cp2 is equal to 10 P without external noise.

FIG. 7 shows the simulation results when the first parallel capacitor Cp1 and the second parallel capacitor Cp2 are both equal to 10 P in the presence of external ramp noise.

FIG. 8 shows the simulation results when the first parallel capacitor Cp1 and the second parallel capacitor Cp2 are both equal to 10 P in the presence of external sine noise.

FIG. 9 shows a flowchart of the noise cancellation circuit operation method in another preferred embodiment of the invention.

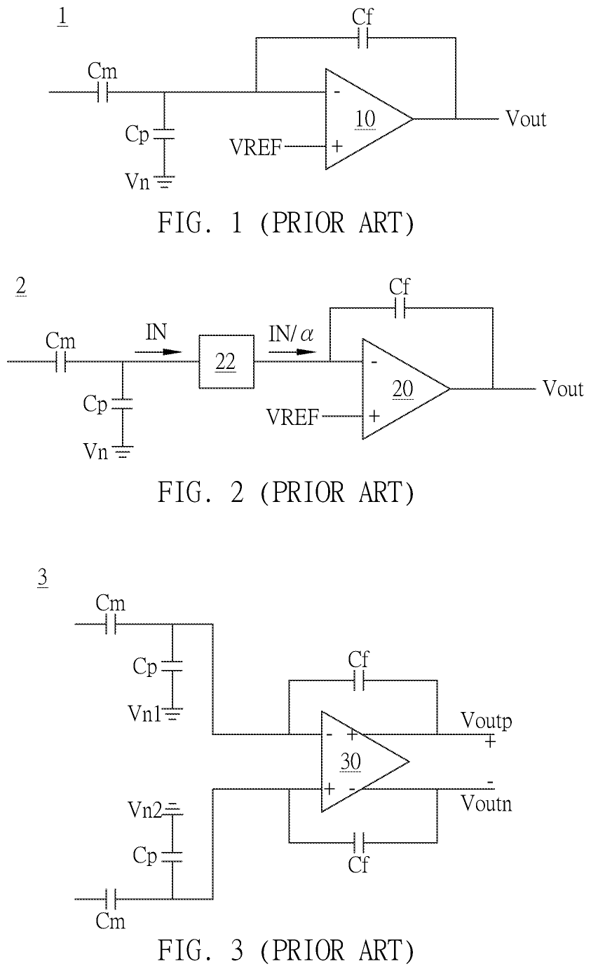

### DETAILED DESCRIPTION OF THE INVENTION

An embodiment of the invention is a noise cancellation circuit. In this embodiment, the noise cancellation circuit can be applied to capacitive touch sensing, such as noise cancellation for self-capacitive touch sensing, to improve the accuracy of touch sensing, but not limited to this.

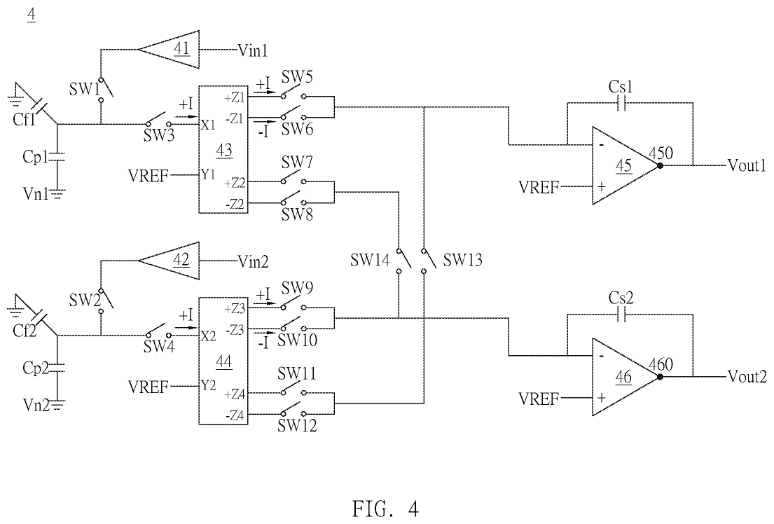

Please refer to FIG. 4. FIG. 4 is a schematic diagram of the noise cancellation circuit in this embodiment. As shown in FIG. 4, the noise cancellation circuit 4 includes a first switch SW1 to a fourteenth switch SW14, a first analog buffer 41, a second analog buffer 42, a first current conveyor 43, a second current conveyor 44, a first operational amplifier 45, a second operational amplifier 46, a first feedback capacitor Cf1, a second feedback capacitor Cf2, a first parallel capacitor Cp1, a second parallel capacitor Cp2, a first series capacitor Cs1 and a second series capacitor Cs2.

The first analog buffer 41 receives a first input signal Vin1 and the second analog buffer 42 receives a second input signal Vin2. The first switch SW1 is coupled to the first analog buffer 41 and the second switch SW2 is coupled to the second analog buffer 42. The first feedback capacitor Cf1 is coupled between the first switch SW1 and the ground terminal and the second feedback capacitor Cf2 is coupled between the second switch SW2 and the ground terminal. The first parallel capacitor Cp1 is coupled between the first switch SW1 and the first noise voltage Vn1, and the second parallel capacitor Cp2 is coupled between the second switch SW2 and the second noise voltage Vn2. The third switch SW3 is coupled to the first switch SW1, the first feedback capacitor Cf1 and the first parallel capacitor Cp1 respectively, and the fourth switch SW4 is coupled to the second switch SW2, the second feedback capacitor Cf2 and the second parallel capacitor Cp2 respectively.

The first current conveyor 43 has a first input terminal X1, a second input terminal Y1, a first pair of output terminals +Z1 and −Z1 and a second pair of output terminals +Z2 and −Z2. The first input terminal X1 is coupled to the third switch SW3 and the second input terminal Y1 is coupled to the reference voltage VREF. The second current conveyor 44 has a third input terminal X2, a fourth input terminal Y2, a third pair of output terminals +Z3 and −Z3 and a fourth pair of output terminals +Z4 and −Z4. The third input terminal X2 is coupled to the fourth switch SW4 and the fourth input terminal Y2 is coupled to the reference voltage VREF.

The fifth switch SW5 and the sixth switch SW6 are coupled to the first pair of output terminals +Z1 and −Z1 respectively. The seventh switch SW7 and the eighth switch SW8 are coupled to the second pair of output terminals +Z2 and −Z2 respectively. The ninth switch SW9 and the tenth switch SW10 are coupled to the third pair of output terminals +Z3 and −Z3 respectively. The eleventh switch SW11 and the twelfth switch SW12 are coupled to the fourth pair of output terminals +Z4 and −Z4 respectively.

An input terminal − of the first operational amplifier 45 is coupled to the fifth switch SW5, the sixth switch SW6, the eleventh switch SW11 and the twelfth switch SW12 respectively. Another input terminal + of the first operational amplifier 45 is coupled to the reference voltage VREF. A first output terminal 450 of the first operational amplifier 45 outputs a first output signal Vout1. The thirteenth switch SW13 is coupled among the input terminal − of the first operational amplifier 45, the eleventh switch SW11 and the twelfth switch SW12.

An input terminal − of the second operational amplifier 46 is coupled to the seventh switch SW7, the eighth switch SW8, the ninth switch SW9, and the tenth switch SW10 respectively. Another input terminal + of the second operational amplifier 46 is coupled to the reference voltage VREF. A second output terminal 460 of the second operational amplifier 46 outputs a second output signal Vout2. The fourteenth switch SW14 is coupled among the input terminal of the second operational amplifier 46, the seventh switch SW7 and the eighth switch SW8. The first series capacitor Cs1 is coupled between the first output terminal 450 and the input terminal − of the first operational amplifier 45 and the second series capacitor Cs2 is coupled between the second output terminal 460 and the input terminal − of the second operational amplifier 46.

In this embodiment, the noise cancellation circuit 4 can be operated in a first phase, a second phase, a third phase and a fourth phase, as described below:

When the noise cancellation circuit 4 is operated in the first phase, the first switch SW1 and the second switch SW2 are turned on and the third switch SW3 to the fourteenth switch SW14 are turned off; the first input signal Vin1 and the second input signal Vin2 have a first voltage VH. The first feedback capacitor Cf1, the first parallel capacitor Cp1, the second feedback capacitor Cf2 and the second parallel capacitor Cp2 are all charged to the first voltage VH, wherein the first voltage VH is higher than the reference voltage VREF.

When the noise cancellation circuit 4 is operated in the second phase, the third switch SW3, the fourth switch SW4, the fifth switch SW5, the eighth switch SW8, the ninth switch SW9, the twelfth switch SW12, the thirteenth switch SW13 and the fourteenth switch SW14 are turned on, and the first switch SW1, the second switch SW2, the sixth switch SW6, the seventh switch SW7, the tenth switch SW10 and the eleventh switch SW11 are turned off. At this time, the first output signal Vout1 and the second output signal Vout2 are both differential output signals.

Since the third switch SW3 is turned on, the charges stored in the first feedback capacitor Cf1 and the first parallel capacitor Cp1 charged in the first phase flow through the turned-on third switch SW3 to an input terminal X1 of the first current conveyor 43, so that the first input terminal X1 receives a positive current +I. Since the fifth switch SW5 and the eighth switch SW8 are turned on, the output terminal +Z1 in the first pair of output terminals +Z1 and +Z1 of the first current conveyor 43 will output a positive current +I to the input terminal − of the first operational amplifier 45. And, the output terminal −Z2 in the second pair of output terminals +Z2 and −Z2 of the first current conveyor 43 will output a negative current −I to the input terminal − of the second operational amplifier 46.

Similarly, since the fourth switch SW4 is turned on, the charges stored in the second feedback capacitor Cf2 and the second parallel capacitor Cp2 charged in the first phase flow to the third input terminal X2 of the second current conveyor 44 through the turned-on fourth switch SW4, so that the third input terminal X2 of the second current conveyor 44 receives the positive current +I. Since the ninth switch SW9 and the twelfth switch SW12 are turned on, the output terminal +Z3 in the third pair of output terminals +Z3 and +Z3 of the second current conveyor 44 will output a positive current +I to the input terminal − of the second operational amplifier 46. And, the output terminal −Z4 in the fourth pair of output terminals +Z4 and −Z4 of the second current conveyor 44 outputs a negative current −I to the input terminal − of the first operational amplifier 45.

For example, assuming that the first output signal Vout1 and the second output signal Vout2 when the noise cancellation circuit 4 is operated in the second phase are Vout1a and Vout2a respectively, then

Vout1a={(VH−VREF)*(Cp1−Cp2+Cf1−Cf2)/Cf}+(Vn1*Cp1/Cs) −(Vn2*Cp2/Cs) Equation 1

Vout2a=((VH−VREF)*(Cp2−Cp1+Cf2−Cf1)/Cf)+(Vn2*Cp2/Cs) −(Vn1*Cp1/Cs) Equation 2

When the noise cancellation circuit 4 is operated in the third phase, the first switch SW1 and the second switch SW2 are turned on and the third switch SW3 to the fourteenth switch SW14 are turned off The first input signal Vin1 has a first voltage VH and the second input signal Vin2 has a second voltage VL, wherein the second voltage VL is lower than the reference voltage VREF and the reference voltage VREF is an average value of the first voltage VH and the second voltage VL. The first feedback capacitor Cf1 and the first parallel capacitor Cp1 are charged to the first voltage VH, and the second feedback capacitor Cf2 and the second parallel capacitor Cp2 are charged to the second voltage VL.

When the noise cancellation circuit 4 is operated in the fourth phase, the third switch SW3, the fourth switch SW4, the fifth switch SW5, the seventh switch SW7, the tenth switch SW10, the twelfth switch SW12, and the thirteenth switch SW13 and the fourteenth switch SW14 are turned on and the first switch SW1, the second switch SW2, the sixth switch SW6, the eighth switch SW8, the ninth switch SW9 and the eleventh switch SW11 are turned off. At this time, the first output signal Vout1 and the second output signal Vout2 are both single-ended output signals.

Since the third switch SW3 is turned on, the charges stored in the first feedback capacitor Cf1 and the first parallel capacitor Cp1 charged in the third phase flow through the turned-on third switch SW3 to an input terminal X1 of the first current conveyor 43, so that the first input terminal X1 receives the positive current +I. Since the fifth switch SW5 and the seventh switch SW7 are turned on, the output terminal +Z1 in the first pair of output terminals +Z1 and −Z1 of the first current conveyor 43 will output the positive current +I to the input terminal − of the first operational amplifier 45. And, the output terminal +Z1 in the second pair of output terminals +Z2 of the first current conveyor 43 will output the positive current +I to the input terminal − of the second operational amplifier 46.

Similarly, since the fourth switch SW4 is turned on, the charges stored in the second feedback capacitor Cf2 and the second parallel capacitor Cp2 charged in the third phase flow to the third input terminal X2 of the second current conveyor 44 through the turned-on fourth switch SW4, so that the third input terminal X2 receives the positive current +I. Since the tenth switch SW10 and the twelfth switch SW12 are turned on, the output terminal −Z3 in the third pair of output terminals +Z3 and −Z3 of the second current conveyor 44 will output the negative current −I to the input terminal − of the second operational amplifier 46. And, the output terminal −Z4 in the fourth pair of output terminals +Z4 and −Z4 of the second current conveyor 44 outputs the negative current −I to the input terminal − of the first operational amplifier 45.

For example, assuming that the first output signal Vout1 and the second output signal Vout2 when the noise cancellation circuit 4 is operated in the fourth phase are Vout1b and Vout2b respectively, then

Vout1b=Vout1a+((VH−VREF)*(Cp1+Cp2+Cf1+Cf2)/Cf)+(Vn1*Cp1/Cs)−(Vn2*Cp2/Cs)=2(VH−VREF)(Cp1+Cf1)+2(Vn1*Cp1/Cs)−2(Vn2*Cp2/Cs) Equation 3

Vout2b=Vout2a+{(VH−VREF)*(Cp1+Cp2+Cf1+Cf2)/Cf}+(Vn2*Cp2/Cs)−(Vn1*Cp1/Cs)=2(VH−VREF)(Cp2+Cf2)+2(Vn2*Cp2/Cs)−2(Vn*Cp1/Cs) Equation 4

Assuming that the first noise voltage Vn1 and the second noise voltage Vn2 are substantially equal, and the first parallel capacitor Cp1 and the second parallel capacitor Cp2 are substantially equal, then the following Equations 5 and 6 can be obtained according to Equations 3 and 4:

Vout1b=2(VH−VREF)*(Cp1+Cf1) Equation 5

Vout2b=2(VH−VREF)*(Cp2+Cf2) Equation 6

Assume that S1 and S2 represent the input signals of the first channel and the second channel respectively, and N1 and N2 represent the noises of the first channel and the second channel respectively. If N1 and N2 are substantially equal, the first output signal Vout1 and the second output signal Vout2 are differential output signals Vout1a and Vout2a respectively when operating in the second phase:

Vout1a=(S1+N1)−(S2+N2)˜(S1−S2) Equation 7

Vout2a=(S2+N2)−(S1+N1)˜(S2−S1) Equation 8

The first output signal Vout1 and the second output signal Vout2 are single-ended output signals Vout1b and Vout2b respectively when the noise cancellation circuit 4 is operated in the fourth phase:

$$\begin{matrix}Vout 1 b = Vout 1 a + [ ( S 1 + N 1 ) - ( - S 2 + N 2 ) ] ∼ ( S 1 - S 2 ) + ( S 1 + S 2 ) = 2 S 1 & Equation 9 \\ Vout 2 b = Vout 2 a + [ - ( - S 2 + N 2 ) + ( S 1 + N 1 ) ] ∼ ( S 2 - S 1 ) + ( S 2 + S 1 ) = 2 S 2 & Equation 10\end{matrix}$$

Therefore, after proper control signal selection (such as modulation and demodulation), it can be obtained that the output terminal presents change amount of the single-ended output signal and can effectively eliminate common-mode noise. It should be noted that the invention is not limited to the adjacent channels or two channels described in the above embodiments, and can also be applied to noise cancellation of more than two channels.

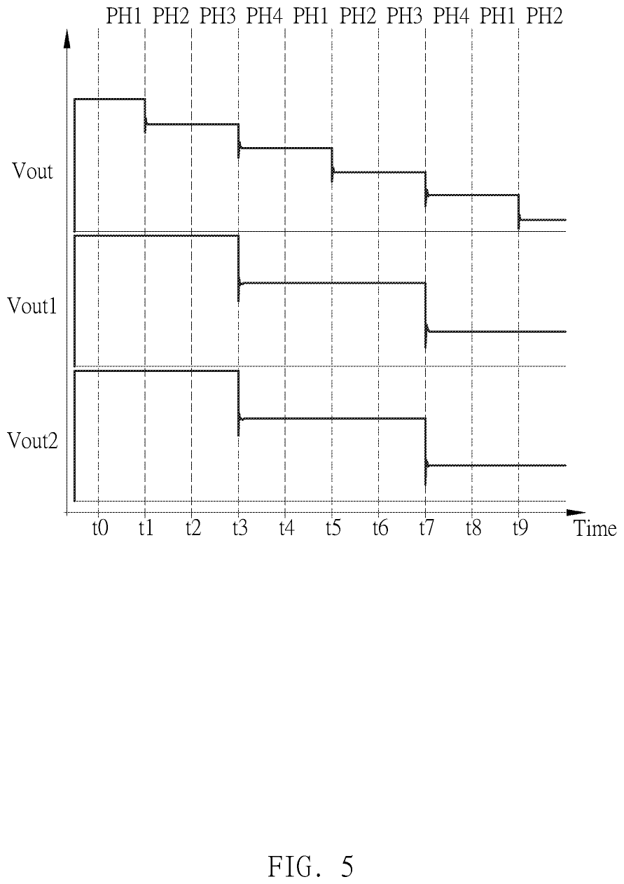

Next, please refer to FIG. 5 to FIG. 8 respectively.

FIG. 5 shows the simulation results when the first parallel capacitor Cp1 and the second parallel capacitor Cp2 are both equal to 10 P without external noise. As shown in FIG. 5, in the absence of external noise, when the noise cancellation circuit 4 is operated in the first phase PH1 (for example, from the time t0 to the time t1), the single-ended output signal Vout maintains its voltage unchanged; when the noise cancellation circuit 4 is switched from the first phase PH1 to the second phase PH2 (for example, at the time t1), the voltage of the single-ended output signal Vout decreases; when the noise cancellation circuit 4 is operated in the second phase (for example, from the time t1 to the time t2), the single-ended output signal Vout is maintained unchanged; when the noise cancellation circuit 4 is switched from the second phase PH2 to the third phase PH3 (for example, at time t2), the single-ended output signal Vout is maintained unchanged; when the noise cancellation circuit 4 is operated in the third phase PH3 (for example, from the time t2 to the time t3), the single-ended output signal Vout is maintained unchanged; when the noise cancellation circuit 4 is switched from the third phase PH3 to the fourth phase PH4 (for example, at the time t3), the voltage of the single-ended output signal Vout drops; when the noise cancellation circuit 4 is operated in the fourth phase (for example, from the time t3 to the time t4), the single-ended output signal Vout is maintained unchanged; when the noise cancellation circuit 4 is switched from the fourth phase PH4 back to the first phase PH1 (for example, at the time t4), the single-ended output signal Vout is maintained unchanged. As for the voltages of the first output signal Vout1 and the second output signal Vout2, the voltages of the first output signal Vout1 and the second output signal Vout2 drop when the noise cancellation circuit 4 is switched from the third phase PH3 to the fourth phase PH4 (for example, at the time t3), and the voltages remain unchanged for the rest of the time. The rest can be deduced by analogy and will not be repeated here.

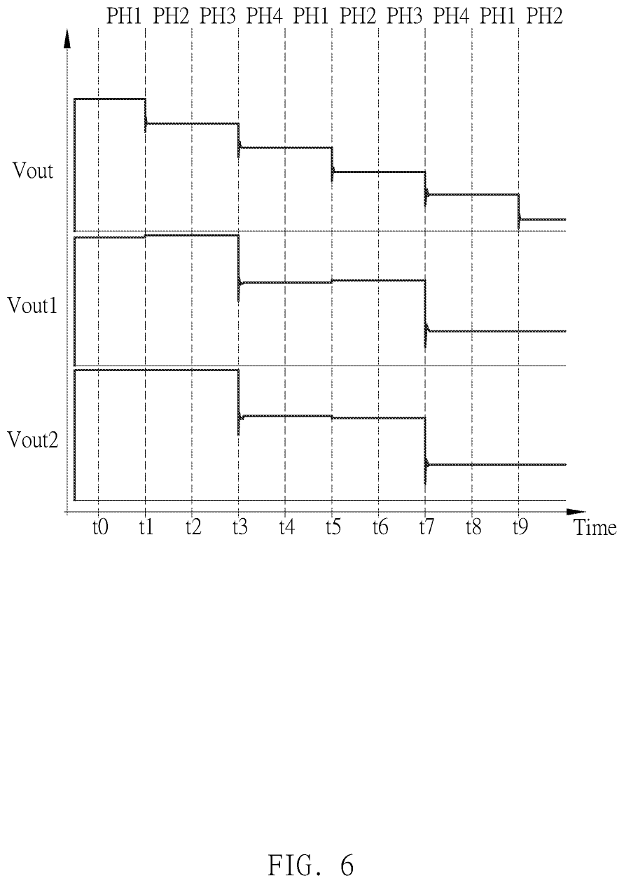

FIG. 6 shows the simulation results when the first parallel capacitor Cp1 is equal to 8 p and the second parallel capacitor Cp2 is equal to 10 P without external noise. FIG. 6 is similar to FIG. 5, and the difference is that the curves of the first output signal Vout1 and the second output signal Vout2 in FIG. 6 fluctuate slightly due to the difference between the first parallel capacitor Cp1 and the second parallel capacitor Cp2, but the effect is not significant.

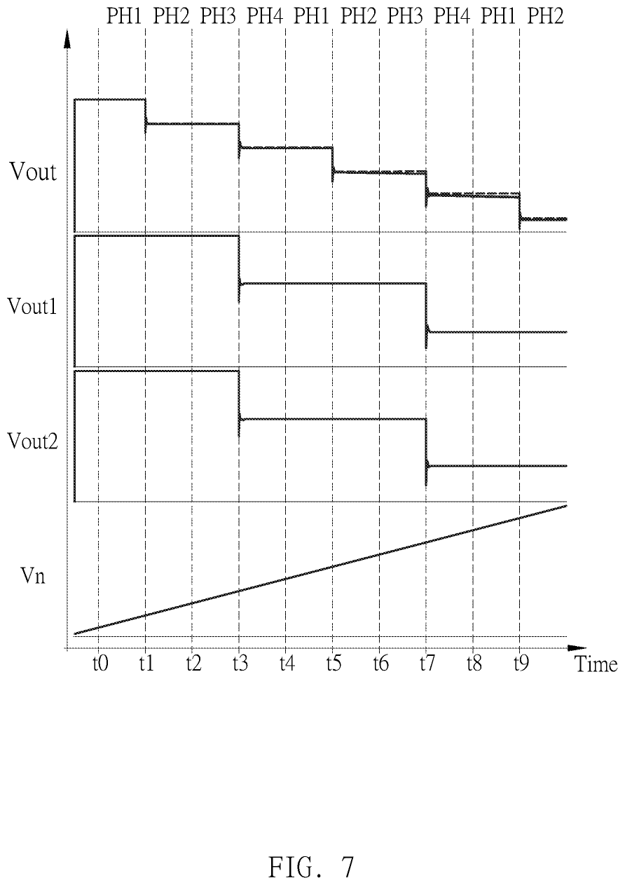

Please refer to FIG. 7. FIG. 7 shows the simulation results when the first parallel capacitor Cp1 and the second parallel capacitor Cp2 are both equal to 10 P in the presence of external ramp noise, wherein the solid line and the dotted line indicate the simulation results with external noise and without external noise respectively. As shown in FIG. 7, the external noise Vn is in the form of a ramp wave; when the noise cancellation circuit 4 is switched from the first phase PH1 to the second phase PH2 (for example, at the time t1) and from the third phase PH3 to the fourth phase PH4 (for example, at the time t3), the voltage of the single-ended output signal Vout decreases significantly, and the voltage is substantially maintained unchanged for the rest of the time; the voltages of the first output signal Vout1 and the second output signal Vout2 drop significantly when the noise cancellation circuit 4 is switched from the third phase PH3 to the fourth phase PH4 (for example, at the time t3), and the voltage is substantially maintained unchanged for the rest of the time. The rest can be deduced by analogy and will not be repeated here.

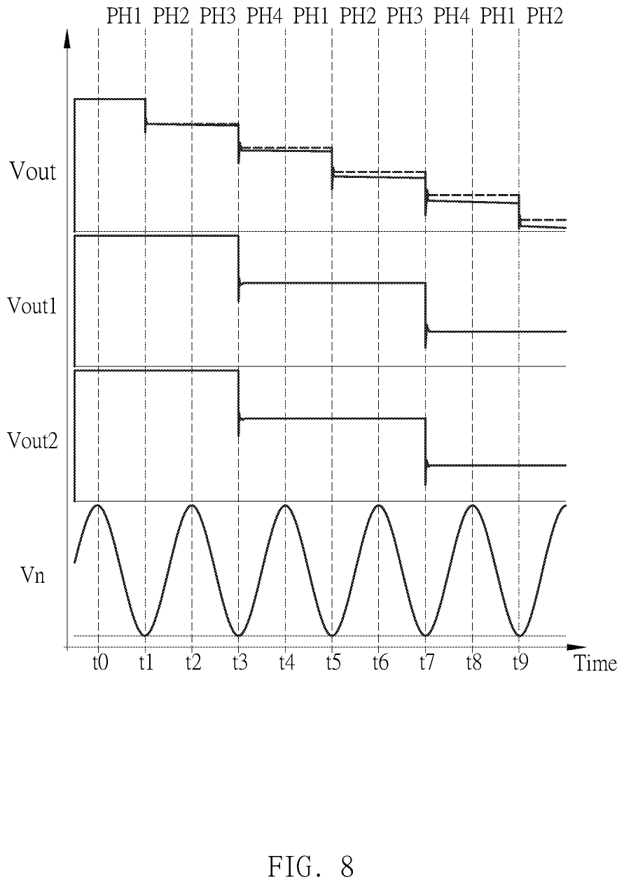

Please refer to FIG. 8. FIG. 8 shows the simulation results when the first parallel capacitor Cp1 and the second parallel capacitor Cp2 are both equal to 10 P in the presence of external sinusoidal (Sine) noise, wherein the solid line and the dotted line indicate the simulation results with external noise and without external noise respectively. As shown in FIG. 8, the external noise Vn is in the form of a sine wave; when the noise cancellation circuit 4 is switched from the first phase PH1 to the second phase PH2 (for example, at the time t1) and from the third phase PH3 to the fourth phase PH4 (for example, at the time t3), the voltage of the single-ended output signal Vout decreases significantly, and the voltage of the single-ended output signal Vout decreases slightly for the rest of the time; the voltages of the first output signal Vout1 and the second output signal Vout2 decrease when the noise cancellation circuit 4 is switched from the third phase PH3 to the fourth phase PH4 (for example, at the time t3), and the voltage is substantially maintained unchanged for the rest of the time. The rest can be deduced by analogy and will not be repeated here.

Another embodiment of the invention is a noise cancellation circuit operating method. In this embodiment, the noise cancellation circuit operation method is used to operate the noise cancellation circuit. The noise cancellation circuit includes a first switch to a fourteenth switch, a first analog buffer, a first feedback capacitor, a first parallel capacitor, a second analog buffer, a second feedback capacitor, a second parallel capacitor, and a first current conveyor, a second current conveyor, a first operational amplifier, a first series capacitor, a second operational amplifier and a second series capacitor.

The first analog buffer receives a first input signal and the second analog buffer receives a second input signal. The first switch is coupled to the first analog buffer and the second switch is coupled to the second analog buffer. The first feedback capacitor is coupled between the first switch and the ground terminal and the second feedback capacitor is coupled between the second switch and the ground terminal. The first parallel capacitor is coupled between the first switch and the first noise voltage and a second parallel capacitor is coupled between the second switch and the second noise voltage. The third switch is coupled to the first switch, the first feedback capacitor and the first parallel capacitor, and the fourth switch is coupled to the second switch, the second feedback capacitor and the second parallel capacitor respectively.

The first current conveyor has a first input terminal, a second input terminal, a first pair of output terminals and a second pair of output terminals. The first input terminal is coupled to the third switch and the second input terminal is coupled to the reference voltage. The second current conveyor has a third input terminal, a fourth input terminal, a third pair of output terminals and a fourth pair of output terminals. The third input terminal is coupled to the fourth switch and the fourth input terminal is coupled to the reference voltage. The fifth switch and the sixth switch are coupled to the first pair of output terminals. The seventh switch and the eighth switch are coupled to the second pair of output terminals. The ninth switch and the tenth switch are coupled to the third pair of output terminals. The eleventh switch and the twelfth switch are coupled to the fourth pair of output terminals.

The input terminal of the first operational amplifier is respectively coupled to the fifth switch, the sixth switch, the eleventh switch and the twelfth switch; the other input terminal of the first operational amplifier is coupled to the reference voltage; and the output terminal of the first operational amplifier outputs the first output signal. The thirteenth switch is coupled among the input terminal of the first operational amplifier, the eleventh switch and the twelfth switch. The input terminal of the second operational amplifier is respectively coupled to the seventh switch, the eighth switch, the ninth switch and the tenth switch; the other input terminal of the second operational amplifier is coupled to the reference voltage, and the output terminal of the second operational amplifier outputs the second output signal. The fourteenth switch is coupled among the input terminal of the second operational amplifier, the seventh switch and the eighth switch. The first series capacitor is coupled between the output terminal and the input terminal of the first operational amplifier and the second series capacitor is coupled between the output terminal and the input terminal of the second operational amplifier.

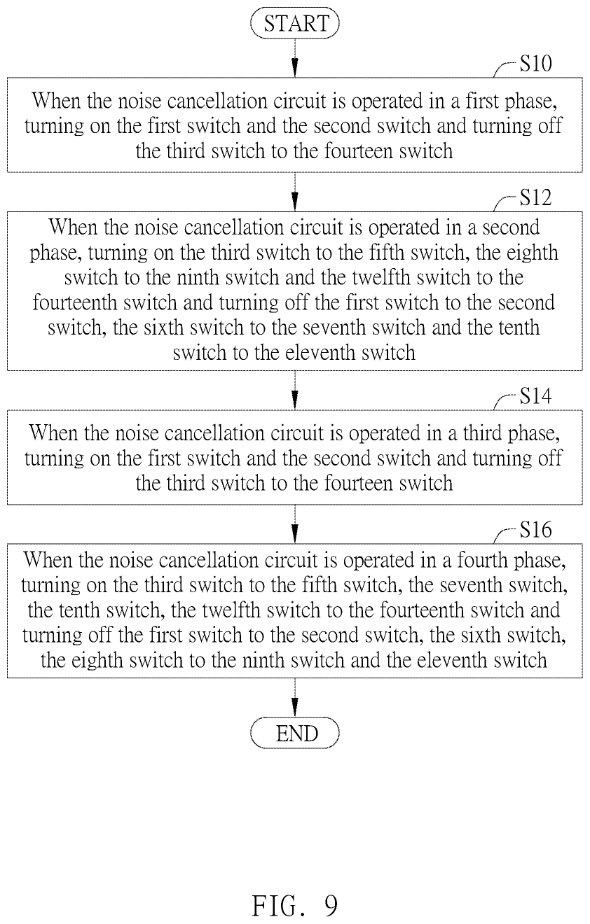

Please refer to FIG. 9. FIG. 9 is a flowchart of the noise cancellation circuit operation method in this embodiment.

As shown in FIG. 9, the noise cancellation circuit operation method can include the following steps:

Step S10: when the noise cancellation circuit is operated in the first phase, turning on the first switch and the second switch and turning off the third switch to the fourteenth switch;

Step S12: when the noise cancellation circuit is operated in the second phase, turning on the third switch, the fourth switch, the fifth switch, the eighth switch, the ninth switch, the twelfth switch, the thirteenth switch and the fourteenth switch and turning off the first switch, the second switch, the sixth switch, the seventh switch, the tenth switch and the eleventh switch;

Step S14: when the noise cancellation circuit is operated in the third phase, turning on the first switch and the second switch and turning off the third switch to the fourteenth switch; and

Step S16: when the noise cancellation circuit is operated in the fourth phase, turning on the third switch, the fourth switch, the fifth switch, the seventh switch, the tenth switch, the twelfth switch, the thirteenth switch and the fourteenth switch and turning off the first switch, the second switch, the sixth switch, the eighth switch, the ninth switch and the eleventh switch.

In practical applications, the noise cancellation circuit can be applied to cancel noise of capacitive touch sensing to improve the accuracy of touch sensing, but not limited to this.

When the noise cancellation circuit is operated in the first phase, both the first input signal and the second input signal have a first voltage, wherein the first voltage is higher than the reference voltage, and the first feedback capacitor, the first parallel capacitor, the second feedback capacitor and the second shunt capacitor are all charged to the first voltage. When the noise cancellation circuit is operated in the second phase, both the first output signal and the second output signal are differential signals.

When the noise cancellation circuit is operated in the third phase, the first input signal has a first voltage and the second input signal has a second voltage, wherein the second voltage is lower than the reference voltage and the reference voltage is an average value of the first voltage and the second voltage. The first feedback capacitor and the first parallel capacitor are charged to the first voltage and the second feedback capacitor and the second parallel capacitor are charged to the second voltage. When the noise cancellation circuit is operated in the fourth phase, the first output signal and the second output signal are both single-ended signals.

Compared to the prior art, the noise cancellation circuit of the invention uses a differential structure to eliminate noise and uses a signal modulation mechanism to modulate back to a single-ended channel change, which can not only effectively reduce external environmental noise, but also prevent the system processing complexity from increasing. Therefore, the disadvantages of the prior art can be greatly improved, and the noise cancellation circuit of the invention can be applied to noise cancellation of capacitive touch sensing to effectively improve the accuracy of capacitive touch sensing.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A noise cancellation circuit, comprising:
a first analog buffer, configured to receive a first input signal;
a first switch, coupled to the first analog buffer;
a first feedback capacitor, coupled between the first switch and a ground terminal;
a first parallel capacitor, coupled between the first switch and a first noise voltage;
a second analog buffer, configured to receive a second input signal;
a second switch, coupled to the second analog buffer;
a second feedback capacitor, coupled between the second switch and the ground terminal;
a second parallel capacitor, coupled between the second switch and a second noise voltage;
a third switch, coupled to the first switch, the first feedback capacitor and the first parallel capacitor respectively;
a first current conveyor having a first input terminal, a second input terminal, a first pair of output terminals and a second pair of output terminals, wherein the first input terminal is coupled to the third switch and the second input terminal is coupled to a reference voltage;
a fourth switch, coupled to the second switch, the second feedback capacitor and the second parallel capacitor respectively;
a second current conveyor having a third input terminal, a fourth input terminal, a third pair of output terminals and a fourth pair of output terminals, wherein the third input terminal is coupled to the fourth switch and the fourth input terminal is coupled to the reference voltage;
a fifth switch and a sixth switch, coupled to the first pair of output terminals;
a seventh switch and an eighth switch, coupled to the second pair of output terminals;
a ninth switch and a tenth switch, coupled to the third pair of output terminals;
an eleventh switch and a twelfth switch, coupled to the fourth pair of output terminals;
a first operation amplifier, wherein an input terminal of the first operation amplifier is coupled to the fifth switch, the sixth switch, the eleventh switch and the twelfth switch respectively, another input terminal of the first operation amplifier is coupled to the reference voltage, and an output terminal of the first operation amplifier outputs a first output signal;
a first series capacitor, coupled between the output terminal and the input terminal of the first operation amplifier;
a thirteen switch, coupled among the input terminal of the first operation amplifier, the eleventh switch and the twelfth switch;
a second operation amplifier, wherein an input terminal of the second operation amplifier is coupled to the seventh switch, the eighth switch, the ninth switch and the tenth switch respectively, another input terminal of the second operation amplifier is coupled to the reference voltage, and an output terminal of the second operation amplifier outputs a second output signal;
a second series capacitor, coupled between the output terminal and the input terminal of the second operation amplifier; and
a fourteen switch, coupled among the input terminal of the second operation amplifier, the seventh switch and the eighth switch.

2. The noise cancellation circuit of claim 1, wherein when the noise cancellation circuit is operated in a first phase, the first switch and the second switch are turned on and the third switch to the fourteen switch are turned off; the first input signal and the second input signal both have a first voltage; the first feedback capacitor, the first parallel capacitor, the second feedback capacitor and the second parallel capacitor are all charged to the first voltage, and the first voltage is higher than the reference voltage.

3. The noise cancellation circuit of claim 2, wherein when the noise cancellation circuit is operated in a second phase, the third switch to the fifth switch, the eighth switch to the ninth switch and the twelfth switch to the fourteenth switch are turned on and the first switch to the second switch, the sixth switch to the seventh switch and the tenth switch to the eleventh switch are turned off; the first output signal and the second output signal are both differential signals.

4. The noise cancellation circuit of claim 3, wherein when the noise cancellation circuit is operated in a third phase, the first switch and the second switch are turned on and the third switch to the fourteen switch are turned off; the first input signal has the first voltage and the second input signal has a second voltage; the first feedback capacitor and the first parallel capacitor are charged to the first voltage and the second feedback capacitor and the second parallel capacitor are charged to the second voltage; the second voltage is lower than the reference voltage and the reference voltage is an average value of the first voltage and the second voltage.

5. The noise cancellation circuit of claim 4, wherein when the noise cancellation circuit is operated in a fourth phase, the third switch to the fifth switch, the seventh switch, the tenth switch and the twelfth switch to the fourteenth switch are turned on and the first switch to the second switch, the sixth switch, the eighth switch to the ninth switch and the eleventh switch are turned off; the first output signal and the second output signal are both single-ended signals.

6. The noise cancellation circuit of claim 1, wherein the noise cancellation circuit is applied to cancel noise of capacitive touch sensing to increase accuracy of capacitive touch sensing.

7. A noise cancellation circuit operating method, used to operate a noise cancellation circuit, the noise cancellation circuit comprising a first switch to a fourteen switch, a first analog buffer, a first feedback capacitor, a first parallel capacitor, a second analog buffer, a second switch, a second feedback capacitor, a second parallel capacitor, a first current conveyor, a second current conveyor, a first operation amplifier, a first series capacitor, a second operation amplifier and a second series capacitor; the first analog buffer receiving a first input signal and the second analog buffer receiving a second input signal; the first switch being coupled to the first analog buffer and the second switch being coupled to the second analog buffer; the first feedback capacitor being coupled between the first switch and a ground terminal and the second feedback capacitor being coupled between the second switch and the ground terminal; the first parallel capacitor being coupled between the first switch and a first noise voltage and the second parallel capacitor being coupled between the second switch and a second noise voltage; the third switch being coupled to the first switch, the first feedback capacitor and the first parallel capacitor respectively and the fourth switch being coupled to the second switch, the second feedback capacitor and the second parallel capacitor respectively; the first current conveyor having a first input terminal, a second input terminal, a first pair of output terminals and a second pair of output terminals; the first input terminal being coupled to the third switch and the second input terminal being coupled to a reference voltage; the second current conveyor having a third input terminal, a fourth input terminal, a third pair of output terminals and a fourth pair of output terminals; the third input terminal being coupled to the fourth switch and the fourth input terminal being coupled to the reference voltage; the fifth switch and the sixth switch being coupled to the first pair of output terminals; the seventh switch and the eighth switch being coupled to the second pair of output terminals; the ninth switch and the tenth switch being coupled to the third pair of output terminals; the eleventh switch and the twelfth switch being coupled to the fourth pair of output terminals; an input terminal of the first operation amplifier being coupled to the fifth switch, the sixth switch, the eleventh switch and the twelfth switch respectively, another input terminal of the first operation amplifier being coupled to the reference voltage, and an output terminal of the first operation amplifier outputting a first output signal; the thirteen switch being coupled among the input terminal of the first operation amplifier, the eleventh switch and the twelfth switch; an input terminal of the second operation amplifier being coupled to the seventh switch, the eighth switch, the ninth switch and the tenth switch respectively, another input terminal of the second operation amplifier being coupled to the reference voltage, and an output terminal of the second operation amplifier outputting a second output signal; the fourteen switch being coupled among the input terminal of the second operation amplifier, the seventh switch and the eighth switch; the first series capacitor being coupled between the output terminal and the input terminal of the first operation amplifier; the second series capacitor being coupled between the output terminal and the input terminal of the second operation amplifier; the noise cancellation circuit operating method comprising steps of:
(a) when the noise cancellation circuit is operated in a first phase, turning on the first switch and the second switch and turning off the third switch to the fourteen switch;
(b) when the noise cancellation circuit is operated in a second phase, turning on the third switch to the fifth switch, the eighth switch to the ninth switch and the twelfth switch to the fourteenth switch and turning off the first switch to the second switch, the sixth switch to the seventh switch and the tenth switch to the eleventh switch;
(c) when the noise cancellation circuit is operated in a third phase, turning on the first switch and the second switch and turning off the third switch to the fourteen switch; and
(d) when the noise cancellation circuit is operated in a fourth phase, turning on the third switch to the fifth switch, the seventh switch, the tenth switch, the twelfth switch to the fourteenth switch and turning off the first switch to the second switch, the sixth switch, the eighth switch to the ninth switch and the eleventh switch.

8. The noise cancellation circuit operating method of claim 7, wherein when the noise cancellation circuit is operated in the first phase, the first input signal and the second input signal both have a first voltage; the first feedback capacitor, the first parallel capacitor, the second feedback capacitor and the second parallel capacitor are all charged to the first voltage, and the first voltage is higher than the reference voltage.

9. The noise cancellation circuit operating method of claim 7, wherein when the noise cancellation circuit is operated in the second phase, the first output signal and the second output signal are both differential signals.

10. The noise cancellation circuit operating method of claim 7, wherein when the noise cancellation circuit is operated in the third phase, the first input signal has the first voltage and the second input signal has a second voltage; the first feedback capacitor and the first parallel capacitor are charged to the first voltage and the second feedback capacitor and the second parallel capacitor are charged to the second voltage; the second voltage is lower than the reference voltage and the reference voltage is an average value of the first voltage and the second voltage.

11. The noise cancellation circuit operating method of claim 7, wherein when the noise cancellation circuit is operated in the fourth phase, the first output signal and the second output signal are both single-ended signals.

12. The noise cancellation circuit operating method of claim 7, wherein the noise cancellation circuit is applied to cancel noise of capacitive touch sensing to increase accuracy of capacitive touch sensing.
